(19) United States
(12) Patent Application Publication
(10) Pub. No.: US 2003/0015700 A1
(43) Pub. Date: Jan. 23, 2003

(54) Suitable semiconductor structure for forming multijunction solar cell and method for forming the same

(75) Inventors: Kurt W. Eisenbeiser, Tempe, AZ (US); Thomas Freeburg, Arlington Heights, IL (US); E. James Prendergast, Phoenix, AZ (US); William J. Ooms, Prescott, AZ (US); Ravindranath Droopad, Chandler, AZ (US); Jamal Ramdani, Chandler, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/908,860

(22) Filed: Jul. 20, 2001

(51) Int. Cl. H01L 29/04; H01L 31/036; H01L 31/0376

(52) U.S. Cl. 257/53; 257/64; 257/75; 257/461

(57) ABSTRACT

Multijunction solar cell structures (100) including high quality epitaxial layers of monocrystalline semiconductor materials that are grown overlying monocrystalline substrates (102) such as large silicon wafers by forming a compliant substrate for growing the monocrystalline layers are disclosed. One way to achieve the formation of a compliant substrate includes first growing an accommodating buffer layer (104) on a silicon wafer. The accommodating buffer (104) layer is a layer of monocrystalline material spaced apart from the silicon wafer by an amorphous interface layer (112) of silicon oxide. The amorphous interface layer (112) dissipates strain and permits the growth of a high quality monocrystalline oxide accommodating buffer layer. Multiple and varied accommodating buffer layers can be used to achieve the monolithic integration of multiple non-lattice matched solar cell junctions.

### FIELD OF THE INVENTION

This invention relates generally to semiconductor structures and devices and to a method for their fabrication, and more specifically to multijunction solar cell devices including semiconductor structures and to methods of forming the structures and devices.

### BACKGROUND OF THE INVENTION

Solar cells generally include a p-n junction formed of adjacent layers or regions of a semiconductor structure. For example, a solar cell may include a p-n junction formed of oppositely doped regions of a semiconductor substrate such as silicon or adjacent layers of oppositely doped semiconductor layers such as GaAs and AlGaAs.

Efficiency of a solar cell, defined as power output divided by power supplied to the cell, is typically about 10-20% for a single p-n junction exposed to direct sunlight. The efficiency of a solar cell generally depends on the wavelength(s) of incident light and the band gap of the semiconductor material: photons having less energy than the bandgap energy of the semiconductor material will not be converted to current, whereas incident photons having an energy equal to or greater than the bandgap of the material will be absorbed by the material and the photon energy will be converted to electricity.

The efficiency of a solar cell can be increased by creating additional p-n junctions designed to convert light of varying wavelengths or energy into current. For example, a multijunction solar cell may be formed which includes multiple, adjacent p-n junctions, in which the top most p-n junction absorbs the high energy photons and the underlying p-n junctions are designed to convert progressively lower energy photons into electricity. Although adding additional p-n junctions may increase the efficiency of the solar cell, light of various wavelength may not be efficiently absorbed by any of the semiconductor layers.

The efficiency of solar cells is also generally a function of defect density of the semiconductor material comprising the cell. The efficiency of the cell generally decreases as the number of defects in the semiconductor material increases. Accordingly, semiconductor structures including multiple layers of oppositely-doped, low defect density material are desirable to form high-efficiency multijunction solar cells.

For many years, attempts have been made to grow various monocrystalline thin films such as GaAs on a foreign substrate such as silicon. These attempts have generally been unsuccessful because lattice mismatches between the host crystal and the grown crystal have caused the resulting layer to be of low crystalline quality.

If a large area thin film of high quality monocrystalline material was available at low cost, a multijunction solar cell device could advantageously be fabricated using that film. In addition, if thin films of high quality monocrystalline material could be realized beginning with a bulk wafer such as a silicon wafer, an integrated device structure could be achieved that took advantage of the best properties of both the silicon and the high quality monocrystalline material layers.

Accordingly, a need exists for a semiconductor structure, suitable for forming multijunction solar cell devices, that provides for the monolithic integration of multiple non-lattice matched solar cell junctions and for a process for making such a structure.

### BRIEF DESCRIPTION OF THE DRAWINGS

The present invention is illustrated by way of example and not limitation in the accompanying figures, in which like references indicate similar elements, and in which:

FIGS. 1, 2, 3, and 4 illustrate schematically, in cross section, device structures in accordance with various embodiments of the invention;

FIG. 5 illustrates graphically the relationship between maximum attainable film thickness and lattice mismatch between a host crystal and a grown crystalline overlayer;

FIG. 6 illustrates a high resolution Transmission Electron Micrograph of a structure including a monocrystalline accommodating buffer layer;

FIG. 7 illustrates an x-ray diffraction spectrum of a structure including a monocrystalline accommodating buffer layer;

FIG. 8 illustrates a high resolution Transmission Electron Micrograph of a structure including an amorphous oxide layer;

FIG. 9 illustrates an x-ray diffraction spectrum of a structure including an amorphous oxide layer;

FIGS. 10-13 illustrate schematically, in cross-section, the formation of a device structure in accordance with another embodiment of the invention;

FIGS. 14-17 illustrate a probable molecular bonding structure of the device structures illustrated in FIGS. 10-13;

FIG. 18 illustrates a device structure including a multifunction solar cell in accordance with the present invention; and

FIG. 19 illustrates a device structure in accordance with yet another embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

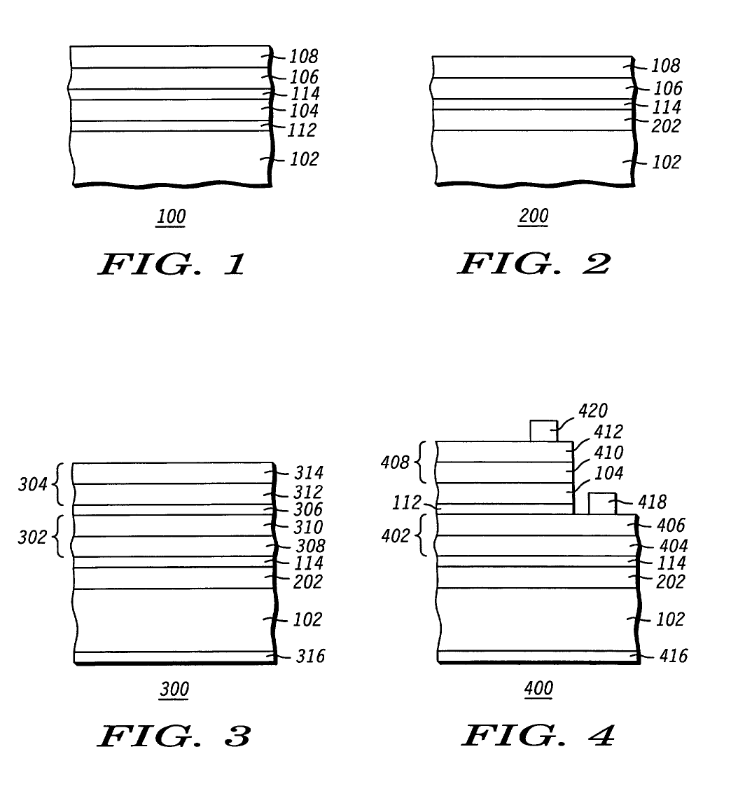

FIG. 1 illustrates schematically, in cross section, a portion of a semiconductor structure 100, suitable for forming a multifunction solar cell, in accordance with an embodiment of the invention. Semiconductor structure 100 includes a monocrystalline substrate 102, an accommodating buffer layer 104 comprising a monocrystalline material, a monocrystalline p-type semiconductor layer 106, a monocrystalline n-type semiconductor layer 108. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 100 also includes an amorphous intermediate layer 112 positioned between substrate 102 and accommodating buffer layer 104. Structure 100 may also include a template layer 114 between accommodating buffer layer 104 and layer 106. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 102, in accordance with an embodiment of the invention, is a monocrystalline semiconductor or compound semiconductor wafer, preferably of large diameter. The wafer can be of, for example, a material from Group IV of the periodic table, and preferably a material from Group IVB. Examples of Group IV semiconductor materials include silicon, germanium, mixed silicon and germanium, mixed silicon and carbon, mixed silicon, germanium and carbon, and the like. Preferably substrate 102 is a wafer containing silicon or germanium, and most preferably is a high quality monocrystalline silicon wafer as used in the semiconductor industry. Accommodating buffer layer 104 is preferably a monocrystalline oxide or nitride material epitaxially grown on the underlying substrate. In accordance with one embodiment of the invention, amorphous intermediate layer 112 is grown on substrate 102 at the interface between substrate 102 and the growing accommodating buffer layer by the oxidation of substrate 102 during the growth of layer 104. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layers 106 and 108.

Use of a silicon substrate may be advantageous for several reasons. For example, silicon is a relatively good conductor of heat, and thus solar cell device performance may be increased by using a silicon substrate to dissipate heat.

Accommodating buffer layer 104 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are intrinsically insulators, although strontium ruthenate, for example, is a conductor. As discussed in more detail below, the intrinsic insulator oxides and nitrides may be suitably doped to form conducting accommodating buffer layers as desired. Generally, the accommodating buffer materials are metal oxides or metal nitrides, and more particularly, these metal oxide or nitrides typically include at least two different metallic elements. In some specific applications, the metal oxides or nitrides may include three or more different metallic elements.

Amorphous interface layer 112 is preferably an oxide formed by the oxidation of the surface of substrate 102, and more preferably is composed of a silicon oxide. The thickness of layer 112 is sufficient to relieve strain attributed to mismatches between the lattice constants of substrate 102 and accommodating buffer layer 104. Typically, layer 112 has a thickness in the range of approximately 0.5-5 nm.

The material for monocrystalline material layers 106 and 108 can be selected, as desired, for a particular structure or application. For example, the monocrystalline material of layers 106 and 108 may comprise compound semiconductor material which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAIAs), indium phosphide (InP), gallium indium phosphide (GaInP), aluminum indium phosphide (AlInP), indium gallium arsenic phosphide (InGaAsP), and the like. Layers 106 and 108 may be separately grown layers of semiconductor materials, with a suitable dopant added to one or both of the layers to form the p-type and n-type materials, or layers 106 and 108 may be formed of a single semiconductor layer, which is suitably doped to form layers 106 and 108.

Appropriate materials for template 114 are discussed below. Suitable template materials chemically bond to the surface of the accommodating buffer layer 104 at selected sites and provide sites for the nucleation of the epitaxial growth of monocrystalline material layer 106. When used, template layer 114 has a thickness ranging from about 1 to about 10 monolayers. As discussed in greater detail below, template layer 114 may also include a surfactant to further relieve any strain that might result from any lattice mismatch between layer 114 and subsequently grown layer 106.

FIG. 2 schematically illustrates, in cross section, a portion of a semiconductor structure 200 in accordance with another exemplary embodiment of the invention. Structure 200 is similar to structure 100, except that structure 200 includes an amorphous layer 202, rather than accommodating buffer layer 104 and amorphous interface layer 112.

As explained in greater detail below, amorphous layer 202 may be formed by first forming an accommodating buffer layer and an amorphous interface layer in a similar manner to that described above. Monocrystalline layer 106 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 202 formed in this manner comprises materials from both the accommodating buffer and interface layers, which amorphous layers may or may not amalgamate. Thus, layer 202 may comprise one or two amorphous layers. Formation of amorphous layer 202 between substrate 102 and monocrystalline layer 106 relieves stresses between layers 102 and 106 and provides a true compliant substrate for subsequent processing—e.g., monocrystalline material layer 108 formation. As previously described with reference to FIG. 1, structure 200 may also include template layer 114 between accommodating buffer layer 104 and layer 106.

In accordance with an alternate embodiment of the invention, the anneal process may be performed after the formation of layer 108. In accordance with yet another embodiment of the invention, a thin layer of monocrystalline material (e.g., material comprising layer 106) may be epitaxially grown over the accommodating buffer layer, and this thin film may serve as an anneal cap during layer 202 formation and as a seed layer for additional material growth for layer 106 formation.

The process previously described above in connection with FIG. 1 is adequate for growing monocrystalline material layers over a monocrystalline substrate. However, the process described in connection with FIG. 2, which includes transforming a monocrystalline accommodating buffer layer to an amorphous oxide layer, may be better for growing monocrystalline material layers because it allows any strain in layers 106 and/or 108 to relax.

FIG. 3 illustrates a semiconductor structure 300 in accordance with yet another embodiment of the invention. Structure 300 is similar to structure 200, except that structure 300 includes additional monocrystalline material layers which form an additional p-n junction thereby producing a multijunction solar cell. The formation of additional p-n junctions of materials of different bandgap energies allows absorption of light over a greater range of wavelengths. Thus, structure 300 may operate more efficiently when exposed to a light source of multiple wavelengths, such as the sun, compared to structures 100 and 200.

Structure 300 includes a substrate 102, a buffer layer 202, and a template layer 114, as described above. In addition, structure 300 includes a bottom junction 302 and a top junction 304 which are separated by an optional conductive passivating layer 306. Bottom junction 302 includes bottom base layer 308, which is epitaxially grown over template 114, and bottom emitter layer 310, which is epitaxially grown over bottom base layer 308. Bottom base layer 308 and bottom emitter layer 310 are formed of suitably doped semiconductor materials and may comprise any of those materials previously described with reference to layers 106 and 108 in FIGS. 1 and 2. For example, structure 300 may include a p-type material such as p-GaAs as layer 308 and an n-type material such as n-GaAs as layer 310.

Top junction 304 includes top base layer 312, which is epitaxially grown over optional conductive passivating layer 306, or alternatively over bottom emitter layer 310, and top emitter layer 314 which is epitaxially grown over top base layer 312. Like layers 308 and 310, layers 312 and 314 are also formed of suitably doped semiconductor materials such as those referred to in describing layers 106 and 108. For example, structure 300 may include an n-type material such as n-InGaP as layer 312 and a p-type material such as p-InGaP as layer 314. Optional conductive passivating layer 306 preferably comprises a lattice matched monocrystalline material with a band gap energy greater than its underlying emitter layer.

The thickness of each of layers 308, 310, 312, and 314 are preferably within a range of about 0.1 to 10 microns while the band gap energies of these various layers preferably range from about 0.2 to 3 eV. Structure 300 includes two junctions. However, a multijunction solar cell made in accordance with the present invention may include as many as 4 junctions.

Structure 300 also includes a back-side conductive material layer 316. Layer 316 may comprise any conductive material and preferably comprises aluminum or gold.

As described above, junction 302 is formed of a material that is different from that used to form junction 304. In accordance with one aspect of this embodiment, junction 302 can convert photons (e.g., low energy photons) that pass through junction 304 and the thickness of layers 312 and 314 is less than the thickness of layers 308 and 310.

FIG. 4 illustrates a two junction, three terminal structure 400 in accordance with a further embodiment of the invention. Structure 400 is similar to structure 300, except that structure 400 includes two more contacts and an additional epitaxial buffer layer to further form multijunction solar cells using non-lattice matched materials. The use of epitaxial oxide buffer layers to accommodate the lattice constant differences in monocrystalline semiconductor materials improves the efficiency of multijunction solar cells. The epitaxial oxide buffer layers also make good low loss tunnel junctions to connect the cells since they can be very thin, e.g. 30 Angstroms, and are, in general, of large bandgap, e.g. >3V.

Like structure 300 described above, structure 400 includes a substrate 102, a buffer layer 202 and a template layer 114. Structure 400 also includes a bottom junction 402 comprising a bottom base layer 404 and a bottom emitter layer 406, which are formed over template 114, an amorphous intermediate layer 112 like that described with reference to FIG. 1 formed over junction 402, and accommodating buffer layer 104 like that described with reference to FIG. 1 formed over layer 112, and a top junction 408 formed over accommodating buffer layer 104. Top junction 408 includes a top emitter layer 412 formed over a top base layer 410.

In this exemplary embodiment, accommodating buffer layer 104 preferably comprises BaZrO₃ and amorphous intermediate layer 112 is formed of any of those materials previously described for layer 112 with reference to FIG. 1. As previously described with reference to FIG. 2, accommodating buffer layer 104 may be exposed to an anneal process to convert the accommodating buffer layer to an amorphous layer like amorphous layer 202 shown in FIG. 2.

Layers 104 and 102 function to relieve stresses between junctions 402 and 408 thereby assisting in the monolithic integration of non-lattice matched solar cell junctions. The layers which comprise junctions 402 and 408 are formed from suitably doped semiconductor materials. For example, in structure 400, layer 404 may comprise an n-type material such as n-GaAs, layer 406 may comprise a p-type material such as p-GaAs, layer 410 may comprise a p-type material such as p-InGaAs, and layer 412 may comprise an n-type material such as n-InGaAs,

Structure 400 also includes back contact layer 416 and additional contacts 418 and 420. Contact layer 416 and contacts 418 and 420 may comprise any suitable conductive material. In addition, although structure 400 is illustrated with only two p-n junctions, any suitable number of p-n junctions may be formed above layer 104 either with or without the aid of additional epitaxial oxide buffer layers.

The following non-limiting, illustrative examples illustrate various combinations of materials useful in structures 100, 200, 300, and 400 in accordance with various alternative embodiments of the invention. These examples are merely illustrative, and it is not intended that the invention be limited to these illustrative examples.

### EXAMPLE 1

In accordance with one embodiment of the invention, monocrystalline substrate 102 is a silicon substrate oriented in the (100) direction. The silicon substrate can be, for example, a silicon substrate as is commonly used in making complementary metal oxide semiconductor (CMOS) integrated circuits having a diameter of about 75-300 mm. In accordance with this embodiment of the invention, accommodating buffer layer 104 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layers 106 and 108. The accommodating buffer layer can have a thickness of about 2 to about 100 nanometers (nm) and preferably has a thickness of about 5 nm. In general, it is desired to have an accommodating buffer layer thick enough to isolate the compound semiconductor layer from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 106 is a compound semiconductor layer of gallium arsenide having a thickness of about 1 nm to about 100 micrometers (μm) and preferably a thickness of about 0.5 μm to 10 μm and layer 108 is a layer of GaAs having a thickness of about 1 nm to about 100 μm and preferably a thickness of about 0.05 μm to 4 μm. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers. GaAs layer 108 may be grown overlying GaAs layer 106 without an additional template.

### EXAMPLE 2

In accordance with a further embodiment of the invention, monocrystalline substrate 102 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700° C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor layers 106 and 108 can be, for example, p-doped and n-doped indium phosphide (InP), indium gallium arsenide (InGaAs), aluminum indium arsenide, (AlInAs), or aluminum gallium indium arsenic phosphide (AlGaInAsP) layers, having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

This example provides exemplary materials useful in structure 200, as illustrated in FIG. 2. Substrate material 102, template layer 114, monocrystalline material layers 106 and 108, and layer 110 may be the same as those described above in connection with example 1.

Amorphous layer 202 is an amorphous oxide layer which is suitably formed of a combination of amorphous intermediate layer materials (e.g., layer 112 materials as described above) and accommodating buffer layer materials (e.g., layer 104 materials as described above). For example, amorphous layer 202 may include a combination of SiOₓ and Sr_{z}Ba_{1-z}TiO₃ (where z ranges from 0 to 1), which combine or mix, at least partially, during an anneal process to form amorphous oxide layer 202.

The thickness of amorphous layer 202 may vary from application to application and may depend on such factors as desired insulating properties of layer 202, type of monocrystalline material comprising layers 106 and 108, and the like. In accordance with one exemplary aspect of the present embodiment, layer 202 thickness is about 2 nm to about 100 nm, preferably about 2-10 nm, and more preferably about 5-6 nm.

### EXAMPLE 4

This example provides exemplary materials useful in structure 300, as illustrated in FIG. 3. Substrate material 102, template layer 114, and layer 110 may be the same as those described above in connection with example 1.

Structure 300 includes an additional p-n junction, configured to increase an efficiency of a solar cell manufactured using structure 300. In accordance with one embodiment of the invention, layer 308 is formed of p-GaAs epitaxially grown material overlying template 114 as described above. Layer 308 is about 0.5 to about 10 microns and preferably about 3 microns thick; layer 310 is a layer of n-GaAs, which is preferably about 0.05 to about 4 microns and preferably about 0.1 microns thick; layer 312 is a p-InGaP layer, which is about 0.1 to about 2 microns and preferably about 0.5 microns thick; and layer 314 is an n-InGaP layer, which is about 0.05 to about 1 micron and preferably about 0.1 microns thick.

### EXAMPLE 5

This example provides exemplary materials useful in structure 400, as illustrated in FIG. 4. Substrate material 102, intermediate layer 112, accommodating buffer layer 104, template layer 114, and layer 202 may be the same as those described above in connection with examples 1-3.

As noted above, structure 400 is similar to structure 300, except structure 400 includes an additional p-n junction 408 formed with another epitaxial oxide buffer layer 104 and intermediate layer 112 and also includes contacts 418 and 420. In accordance with one embodiment of the invention, junction 408 is formed by epitaxially growing a p-InP layer overlying oxide buffer layer 104 and an n-InP layer overlying the p-InP layer where the p-InP layer preferably has a thickness of about 0.5 to 10 microns, the oxide buffer layer 104 preferably has a thickness of about 1 to 10 nm, and the n-InP layer preferably has a thickness of about 0.5 to 4 microns. In accordance with the illustrated embodiment, conductive layer 404 is a metal layer and is about 0.1 nm to about 100 nm thick.

Referring again to FIGS. 1-4, substrate 102 is a monocrystalline substrate such as a monocrystalline silicon, germanium, or gallium arsenide substrate. The crystalline structure of the monocrystalline substrate is characterized by a lattice constant and by a lattice orientation. In similar manner, accommodating buffer layer 104 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 5 illustrates graphically the relationship of the achievable thickness of a grown crystal layer of high crystalline quality as a function of the mismatch between the lattice constants of the host crystal and the grown crystal. Curve 502 illustrates the boundary of high crystalline quality material. The area to the right of curve 502 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 102 is a (100) or (111) oriented monocrystalline silicon wafer and accommodating buffer layer 104 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 112, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-4, layer 106 (or layer 308 or 404) is a layer of epitaxially grown monocrystalline material and that crystalline material is also characterized by a crystal lattice constant and a crystal orientation. In accordance with one embodiment of the invention, the lattice constant of layer 106 differs from the lattice constant of substrate 102. To achieve high crystalline quality in this epitaxially grown monocrystalline layer, the accommodating buffer layer must be of high crystalline quality. In addition, in order to achieve high crystalline quality in layer 106, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa_{1-z}TiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved. Similarly, layers formed above layer 106 (or layer 302 illustrated in FIG. 3) are formed by epitaxially growing material that is closely lattice matched to the underlying layer to allow high quality epitaxial growth of the film.

The following example illustrates a process, in accordance with one embodiment of the invention, for fabricating a semiconductor structure such as the structures depicted in FIGS. 1-4. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of at least 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of at least 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs. After the GaAs layer is formed, subsequent semiconductor layers can be epitaxially formed using an MBE process in a similar manner.

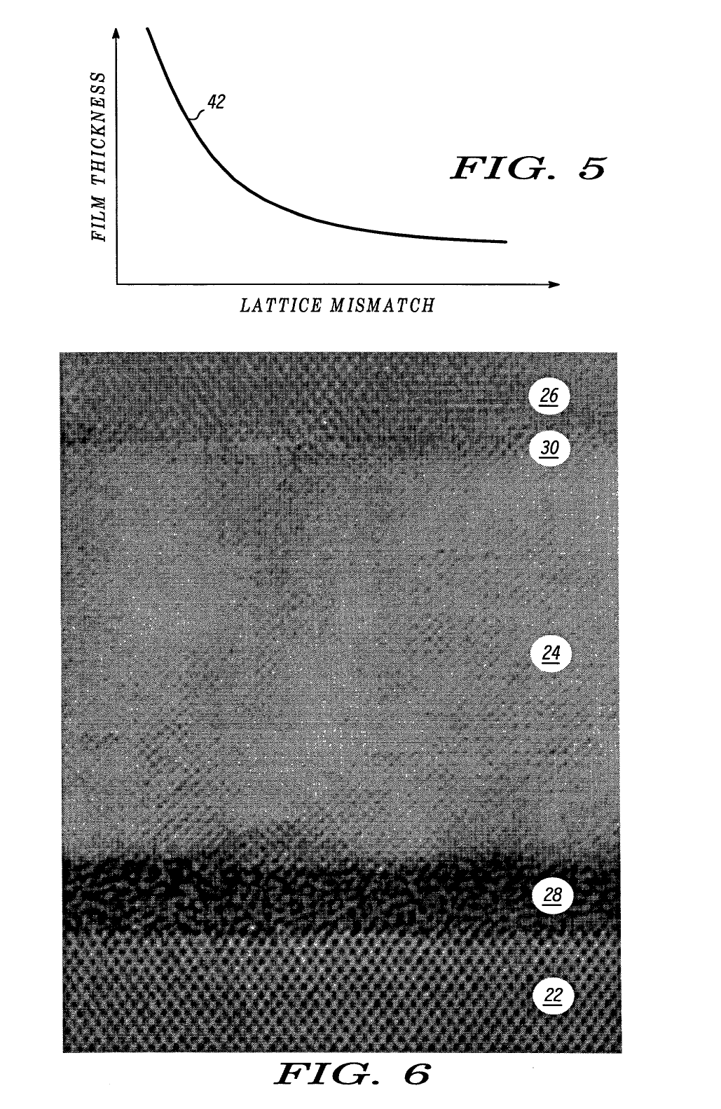

FIG. 6 is a high resolution Transmission Electron Micrograph (TEM) of semiconductor material manufactured in accordance with one embodiment of the present invention. Single crystal SrTiO₃ accommodating buffer layer 104 was grown epitaxially on silicon substrate 102. During this growth process, amorphous interfacial layer 112 is formed which relieves strain due to lattice mismatch. GaAs compound semiconductor layer 106 was then grown epitaxially using template layer 114.

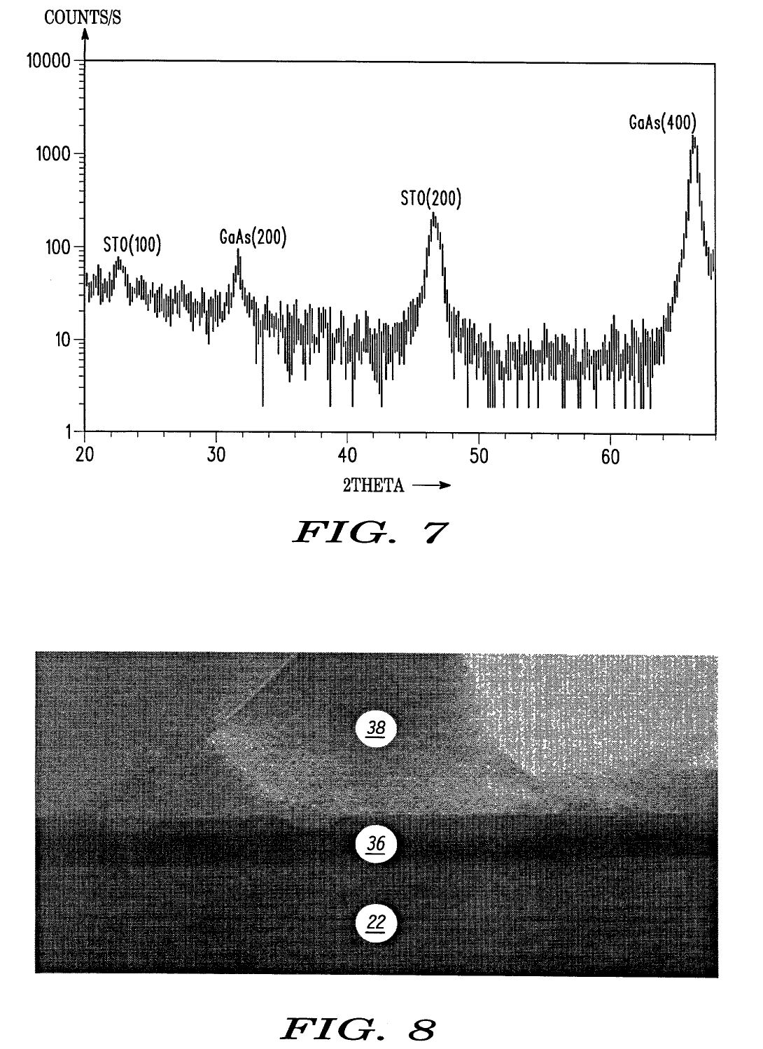

FIG. 7 illustrates an x-ray diffraction spectrum taken on a structure including GaAs monocrystalline layer 106 comprising GaAs grown on silicon substrate 102 using accommodating buffer layer 104. The peaks in the spectrum indicate that both the accommodating buffer layer 104 and GaAs compound semiconductor layer 106 are single crystal and (100) orientated.

Structure 200, illustrated in FIG. 2, may be formed by growing an accommodating buffer layer, forming an amorphous oxide layer over substrate 102, and growing semiconductor layer 106 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 202. Layer 108 is then subsequently grown over layer 106. Alternatively, the anneal process may be carried out subsequent to growth of layer 108.

In accordance with one aspect of this embodiment, layer 202 is formed by exposing substrate 102, the accommodating buffer layer, the amorphous oxide layer, and monocrystalline layer 106 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 202. When conventional thermal annealing is employed to form layer 202, an overpressure of one or more constituents of layer 106 may be required to prevent degradation of layer 106 during the anneal process. For example, when layer 106 includes GaAs, the anneal environment preferably includes an overpressure of arsenic to mitigate degradation of layer 106.

FIG. 8 is a high resolution TEM of semiconductor material manufactured in accordance with the embodiment of the invention illustrated in FIG. 2. In accordance with this embodiment, a single crystal SrTiO₃ accommodating buffer layer was grown epitaxially on silicon substrate 102. During this growth process, an amorphous interfacial layer forms as described above. Next, layer 106 comprising a compound semiconductor layer of GaAs is formed above the accommodating buffer layer and the accommodating buffer layer is exposed to an anneal process to form amorphous oxide layer 202.

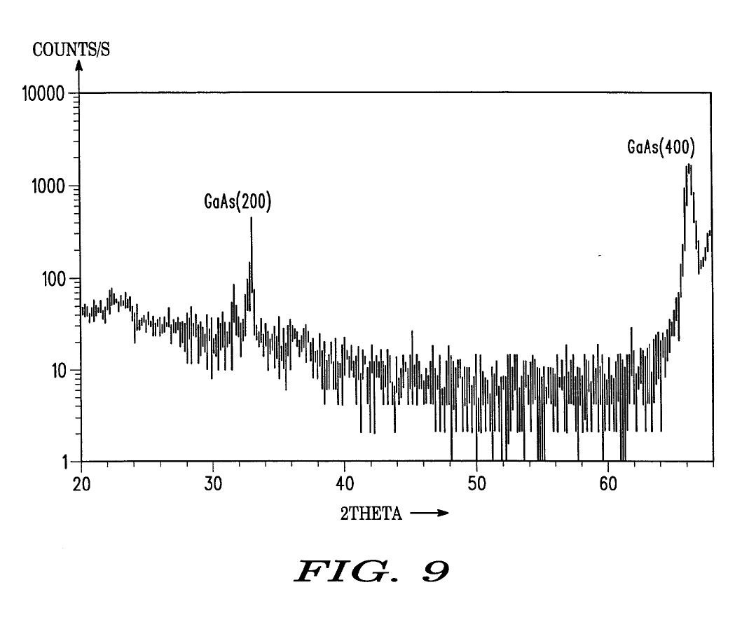

FIG. 9 illustrates an x-ray diffraction spectrum taken on a structure including monocrystalline layer 106 comprising a GaAs compound semiconductor layer and amorphous oxide layer 202 formed on silicon substrate 102. The peaks in the spectrum indicate that GaAs compound semiconductor layer 106 is single crystal and (100) orientated and the lack of peaks around 40 to 50 degrees indicates that layer 202 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

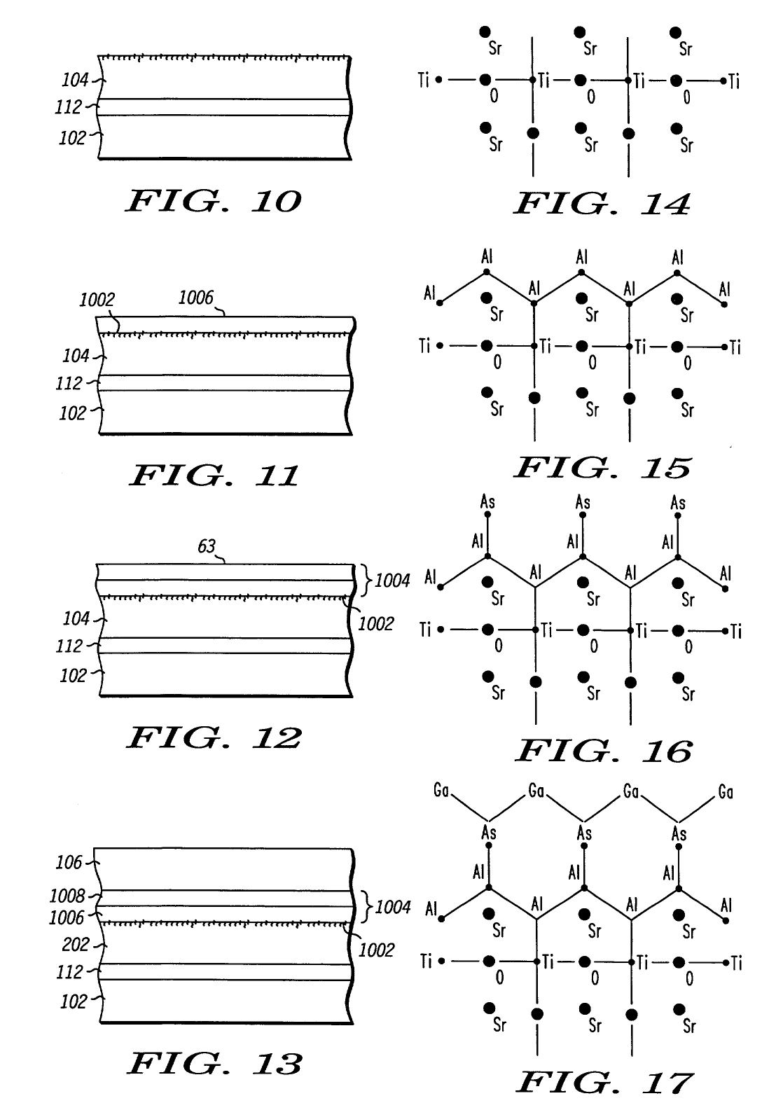

The formation of a device structure in accordance with another embodiment of the invention is illustrated schematically in cross-section in FIGS. 10-13. Like the previously described embodiments referred to in FIGS. 1-4, this embodiment of the invention involves the process of forming a compliant substrate utilizing the epitaxial growth of a single crystal of accommodating buffer layer 104 previously described with reference to FIG. 1 and amorphous layer 202, previously described with reference to FIG. 2, and the formation of a template layer 114. However, the embodiment illustrated in FIGS. 10-13 utilizes a template that includes a surfactant to facilitate layer-by-layer monocrystalline material growth.

Turning now to FIG. 10, an amorphous intermediate layer 112 is grown on substrate 102 at the interface between substrate 102 and a growing accommodating buffer layer 104, which is preferably a monocrystalline oxide layer, by the oxidation of substrate 102 during the growth of layer 104, as described above.

Layer 104 is grown with a strontium terminated surface represented in FIG. 10 by hatched line 1002 which is followed by the addition of a template layer 1004 which includes a surfactant layer 1006 and capping layer 1008 as illustrated in FIGS. 11 and 12. Surfactant layer 1006 may comprise, but is not limited to, elements such as Al, In and Ga, but will be dependent upon the composition of layer 104 and the overlying layer of monocrystalline material for optimal results. In one exemplary embodiment, aluminum is used for surfactant layer 1006 and functions to modify the surface and surface energy of layer 104. Preferably, surfactant layer 1006 is epitaxially grown, to a thickness of one quarter to two monolayers, over layer 104 as illustrated in FIG. 11 by way of molecular beam epitaxy, although other epitaxial processes may also be performed including CVD, MOCVD, MEE, ALE, PVD, CSD, PLD, or the like.

Surfactant layer 1006 is then exposed to a Group V element such as arsenic, for example, to form capping layer 1008 as illustrated in FIG. 12. Surfactant layer 1006 may be exposed to a number of materials to create capping layer 1008 such as elements which include, but are not limited to, As, P, Sb and N. Surfactant layer 1006 and capping layer 1008 combine to form template layer 1004.

Monocrystalline material layer 106, which in this example is a compound semiconductor such as GaAs, is then deposited via MBE, CVD, MOCVD, MEE, ALE, PVD, CSD, PLD, and the like to form the final structure illustrated in FIG. 13.

FIGS. 14-17 illustrate possible molecular bond structures for a specific example of a compound semiconductor structure formed in accordance with the embodiment of the invention illustrated in FIGS. 10-13. More specifically, FIGS. 14-17 illustrate the growth of GaAs (layer 106) on the strontium terminated surface of a strontium titanate monocrystalline oxide (layer 104) using a surfactant containing template (layer 1004).

In order to maintain a true layer by layer growth (Frank Van der Merve growth), the following relationship must be satisfied:

δ_{STO}>(δ_{INT}+δ_{GaAs})

where the surface energy of the monocrystalline oxide layer 104 must be greater than the surface energy of the amorphous interface layer 112 added to the surface energy of the GaAs layer 106. Since it is otherwise impracticable to satisfy this equation, a surfactant containing template was used, as described above with reference to FIGS. 11-13, to increase the surface energy of the monocrystalline oxide layer 104 and also to shift the crystalline structure of the template to a diamond-like structure that is in compliance with the original GaAs layer.

FIG. 14 illustrates the molecular bond structure of a strontium terminated surface of a strontium titanate monocrystalline oxide layer. An aluminum surfactant layer is deposited on top of the strontium terminated surface and bonds with that surface as illustrated in FIG. 15, which reacts to form a capping layer comprising a monolayer of Al₂Sr having the molecular bond structure illustrated in FIG. 15 which forms a diamond-like structure with an sp³ hybrid terminated surface that is compliant with compound semiconductors such as GaAs. The structure is then exposed to As to form a layer of AlAs as shown in FIG. 16. GaAs is then deposited to complete the molecular bond structure illustrated in FIG. 17 which has been obtained by 2D growth. The alkaline earth metals such as those in Group IIA are those elements preferably used to form the capping surface of the monocrystalline oxide layer 104 because they are capable of forming a desired molecular structure with aluminum.

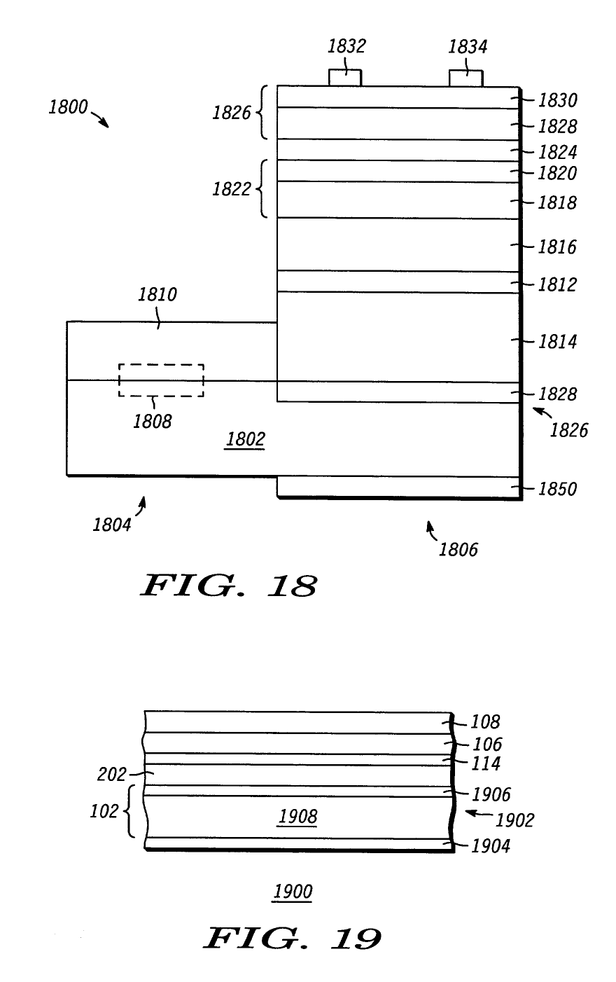

FIG. 18 illustrates schematically, in cross section, a device structure 1800 in accordance with a further embodiment of the invention. Device structure 1800 includes a monocrystalline semiconductor substrate 1802, preferably a monocrystalline silicon, germanium, or gallium arsenide wafer. Monocrystalline semiconductor substrate 1802 includes two regions, 1804 and 1806. An electrical semiconductor component generally indicated by the dashed line 1808 is formed, at least partially, in region 1804. Electrical component 1808 can be a resistor, a capacitor, an active semiconductor component such as a diode or a transistor or an integrated circuit such as a CMOS integrated circuit. For example, electrical semiconductor component 1808 can be a CMOS integrated circuit configured to perform digital signal processing or another function for which silicon integrated circuits are well suited. In accordance with one embodiment of the invention, device 1808 includes circuits for inverters to convert direct current to alternating current or charge controllers. The electrical semiconductor component in region 1804 can be formed by conventional semiconductor processing as is well known and widely practiced in the semiconductor industry. A layer of insulating material 1810 such as a layer of silicon oxide or the like may overlie electrical semiconductor component 1808.

Insulating material 1810 and any other layers that may have been formed or deposited during the processing of semiconductor component 1808 in region 1804 are removed from the surface of region 1806 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 1806 and is reacted with the oxidized surface to form a first template layer (not shown). In accordance with one embodiment of the invention a monocrystalline oxide layer is formed overlying the template layer by a process of molecular beam epitaxy. Reactants including barium, titanium and oxygen are deposited onto the template layer to form the monocrystalline oxide layer. During the deposition, the partial pressure of oxygen is initially set near the minimum necessary to fully react with the barium and titanium to form the monocrystalline barium titanate layer. As the monocrystalline oxide forms, the partial pressure of oxygen is increased to form an amorphous layer between the growing crystalline layer and the substrate.

In accordance with an embodiment of the invention, the step of depositing the monocrystalline oxide layer is terminated by forming a layer 1812, which includes 1-10 monolayers of titanium, barium, strontium, barium and oxygen, titanium and oxygen, or strontium and oxygen, and may additionally include a surfactant (e.g., 1-2 monolayers of Al) and/or a cap layer as discussed above in connection with FIGS. 10-13 and 14-17.

In accordance with one aspect of the present embodiment, after layer 1812 formation, an n-type semiconductor material layer 1816 (e.g., n-type GaAs) is epitaxially grown overlying layer 1812 and the monocrystalline titanate layer is exposed to an anneal process such that the titanate layer forms an amorphous oxide layer 1814. A monocrystalline n-type layer 1818 (e.g., n-type GaAs) is then formed overlying layer 1816 using the method described above. A monocrystalline p-type layer 1820 (e.g., p-type GaAs) is formed overlying layer 1818 to form junction 1822. Another epitaxial oxide buffer layer 1824, formed in accordance with either layer 104 or 202 discussed in FIGS. 1 and 2, respectively, is then formed overlying junction 1822 in order to aid in the epitaxial growth of another junction 1826. Junction 1826 may comprise a p-type layer 1828 and an n-type layer 1830 like any of those previously described with reference to layers 106 and 108 in FIGS. 1 and 2, layers 312 and 314 in FIG. 3, and layers 410 and 412 in FIG. 4. Electrical contacts 1832 and 1834 (e.g., ohmic contacts) are then formed, such that contact may be made to layer 1830.

Structure 1800 may also include a p-n junction formed in substrate 1802 within region 1806. For example, if substrate 1802 includes a p-type doped silicon substrate, junction 1826 is formed by forming an n-type layer 1828 (e.g., using ion implant, diffusion, or epitaxial growth techniques) overlying substrate 1802. In this case, a backside contact 1850 is also formed. A more detailed description of forming a p-n junction in substrate 1802 is made with reference to FIG. 19.

Although illustrative structure 1800 has been described as a structure formed on a silicon substrate 1802 and having a barium (or strontium) titanate layer, similar devices can be fabricated using other monocrystalline substrates, accommodating buffer layers and other monocrystalline material layers as described elsewhere in this disclosure. For example, a device structure in accordance with the present invention may include a solar cell including additional p-n junction layers, p-n junctions formed within the substrate, and a back side contact to increase the efficiency of the solar cell.

FIG. 19 illustrates a structure 1900 in accordance with a further embodiment of the invention. Structure 1900 is similar to structure 200, except that structure 1900 includes an additional p-n junction 1902 formed using substrate 102 and includes an additional back-side conductive material layer 1904. Additional p-n junction 1902 is configured to convert photons to electricity. In accordance with one aspect of this embodiment, p-n structure 1902 is formed of material different from material used to form layers 106 and 108. Thus, junction 1902 can convert photons (e.g., lower energy photons) that pass through layers 106 and 108. In accordance with one aspect of this embodiment, the thickness of layers 106 and 108 is less than the thickness of layers 1906 and 1908.

Structure 1900 preferably includes a conductive accommodating buffer layer 202. As previously noted above, some of the materials suitable to form accommodating buffer layer 202 are conductive. Otherwise insulating buffer layer material may also be used to form layer 202, if suitably doped (e.g., dopant levels at 10¹⁶ to 10¹⁹ atoms per cubic centimeter). Conducting accommodating buffer layer facilitates the transfer of electrons through the various layers of structure 1900 between layer 108 and layer 1904.

Conductive material layer 1904 may comprise any conductive material. For example, in accordance with one embodiment of the invention, layer 1904 includes a metal such as gold, tin, or a combination of chromium and gold.

In accordance with one embodiment of the invention, junction 1902 is formed by epitaxially growing about 250 nm to about 11 micrometers thick n-type layer 1906 overlying p+ silicon substrate 1908. In accordance with the illustrated embodiment, conductive layer 1904 is a metal layer and is about 0.1 nm to about 100 nm thick.

Although illustrated with only one additional p-n junction formed above layer 202, any suitable number of p-n junctions may be formed above layer 202 in accordance with the present invention. For example, layers 308-314, illustrated in FIG. 3, may be formed above layer 202 and p-n junction 1902.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for solar cell devices and other devices employing non-silicon monocrystalline materials should decrease because larger substrates can be processed more economically and more readily compared to the relatively smaller and more fragile substrates (e.g., conventional compound semiconductor wafers).

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A structure for forming a solar cell comprising:
a monocrystalline substrate;
an accommodating buffer layer formed on the substrate;
a first monocrystalline semiconductor layer formed overlying the accommodating buffer layer; and
a second monocrystalline semiconductor layer formed overlying the first monocrystalline semiconductor layer.

2. The semiconductor structure of claim 1, wherein the first and second monocrystalline semiconductor layers each comprise a first type of dopant or second type of dopant.

3. The semiconductor structure of claim 2, wherein the first and second monocrystalline semiconductor layers are each doped with opposite type dopants such that a combination of the first and second monocrystalline layers forms a p-n junction.

4. The semiconductor structure of claim 1, further comprising a template layer formed between the accommodating buffer layer and the first monocrystalline semiconductor layer.

5. The semiconductor structure of claim 1, wherein the template layer comprises a surfactant.

6. The semiconductor structure of claim 5, wherein the surfactant comprises at least one of Al, In, and Ga.

7. The semiconductor structure of claim 5, wherein the template layer further comprises a capping layer.

8. The semiconductor structure of claim 7, wherein the capping layer comprises at least one of As, P, Sb, and N.

9. The semiconductor structure of claim 7, wherein the surfactant comprises Al, the capping layer comprises Al₂Sr, and the first monocrystalline semiconductor layer comprises GaAs.

10. The semiconductor structure of claim 1, wherein the accommodating buffer layer comprises an oxide selected from the group consisting of alkaline earth metal titanates, alkaline earth metal zirconates, alkaline earth metal hafniates, alkaline earth metal tantalates, alkaline earth metal ruthenates, and alkaline earth metal niobates.

11. The semiconductor structure of claim 1, wherein the accommodating buffer layer comprises SrₓBa₁₋ₓTiO₃ where x ranges from 0 to 1.

12. The semiconductor structure of claim 1, wherein the accommodating buffer layer comprises an oxide formed as a monocrystalline oxide and is subsequently heat treated to convert the monocrystalline oxide to an amorphous oxide.

13. The semiconductor structure of claim 1, further comprising an amorphous oxide layer formed between the first monocrystalline substrate and the accommodating buffer layer.

14. The semiconductor structure of claim 13, wherein the monocrystalline substrate comprises silicon and the amorphous oxide layer comprises a silicon oxide.

15. The semiconductor structure of claim 1, wherein the accommodating buffer layer is conductive.

16. The semiconductor structure of claim 1, wherein the first monocrystalline semiconductor layer is a compound semiconductor material selected from the group consisting of: III-V compounds, mixed III-V compounds, II-VI compounds, and mixed II-VI compounds.

17. The semiconductor structure of claim 1, wherein the first monocrystalline semiconductor layer comprises a material selected from the group consisting of: GaAs, AlGaAs, InP, InGaAs, InGaP, InGaAsP, AlInP, and GaInP.

18. The semiconductor structure of claim 3, wherein the first monocrystalline semiconductor layer comprises GaAs of a first dopant type and the second monocrystalline semiconductor layer comprises GaAs of a second dopant type.

19. The semiconductor structure of claim 1, further comprising a plurality of p-n junctions grown on top of the accommodating buffer layer.

20. The semiconductor structure of claim 19, wherein the plurality of p-n junctions comprise semiconductor layers GaAs and GaInP.

21. The semiconductor structure of claim 1, further comprising a p-n junction formed within the monocrystalline substrate.

22. The semiconductor structure of claim 1, further comprising a conductive material layer adjacent and in contact with the monocrystalline substrate.

23. The semiconductor structure of claim 22, wherein the conductive material includes a metal.

24. The semiconductor structure of claim 1, wherein the accommodating buffer layer has a thickness of about 2-10 nm.

25. The semiconductor structure of claim 1, further comprising a microelectronic device formed using the monocrystalline substrate.

26. The semiconductor device of claim 25, wherein the microelectronic device includes a charge controller.

27. The semiconductor device of claim 25, wherein the microelectronic device includes an inverter.

28. The semiconductor structure of claim 20, wherein each of said p-n junctions includes an emitter region and a base region.

29. A multijunction solar cell formed using the structure of claim 19.

30. A structure for forming a solar cell comprising:
a monocrystalline substrate;
a first amorphous oxide layer formed on the substrate;
a monocrystalline semiconductor material of a first type formed overlying the amorphous oxide; and
a monocrystalline semiconductor material of a second type formed over the compound semiconductor material of a first type.

31. The structure of claim 30, wherein the first and second monocrystalline semiconductor layers each comprise a first type of dopant or second type of dopant.

32. The semiconductor structure of claim 31, wherein the first and second monocrystalline semiconductor layers are each doped with opposite type dopants such that a combination of the first and second monocrystalline layers forms a p-n junction.

33. The structure of claim 32, further comprising a multijunction solar cell having a plurality of additional monocrystalline semiconductor layers which form a plurality of additional p-n junctions.

34. The multijunction solar cell of claim 33, further comprising a second amorphous oxide layer.

35. The multijunction solar cell of claim 34, wherein the first and second amorphous oxide layers comprise different materials whose composition depends upon their underlying monocrystalline semiconductor material layer.

36. The multijunction solar cell of claim 35 wherein one of the first and second amorphous oxide layers underlies a GaAs solar cell and comprises SrₓBa₁₋ₓTiO₃ where x ranges from 0 to 1.

37. The multijunction solar cell of claim 36 wherein the other amorphous oxide layer underlies an InGaAs solar cell and comprises BaZrO₃.

38. The structure of claim 30, wherein the monocrystalline substrate comprises silicon.

39. The structure of claim 30, wherein the monocrystalline substrate comprises a p-n junction.

40. The structure of claim 30, further comprising a conductive layer adjacent and in contact with the monocrystalline substrate.

41. The structure of claim 30, wherein the amorphous oxide layer is monocrystalline.

42. The structure of claim 30, wherein the amorphous oxide layer is conductive.

43. The semiconductor structure of claim 30, further comprising a microelectronic device formed using the monocrystalline substrate.

44. The semiconductor device of claim 43, wherein the microelectronic device includes a charge controller.

45. The semiconductor device of claim 42, wherein the microelectronic device includes an inverter.

46. The semiconductor structure of claim 33, wherein each of said p-n junctions includes an emitter region and a base region.

47. A process for fabricating a multijunction solar cell structure comprising the steps of:
providing a monocrystalline substrate;
epitaxially growing a first monocrystalline accommodating buffer layer overlying the monocrystalline substrate; and
epitaxially growing a plurality of monocrystalline semiconductor materials over the monocrystalline accommodating buffer layer, wherein the monocrystalline semiconductor materials comprise p-type and n-type materials which are formed to create a plurality of p-n junctions.

48. The process of claim 47, wherein the step of providing includes providing a silicon substrate.

49. The process of claim 47, further comprising the step of exposing a portion of the structure to an anneal process to convert the monocrystalline accommodating buffer layer to an amorphous structure.

50. The process of claim 47, further comprising the step of forming an amorphous layer between the accommodating buffer layer and the monocrystalline substrate.

51. The process of claim 47, further comprising the step of growing a second monocrystalline accommodating buffer layer overlying at least one of the monocrystalline semiconductor material layers.

52. The process of claim 51, wherein the step of growing a first monocrystalline accommodating buffer layer comprises growing a layer of SrₓBa₁₋ₓTiO₃ to accommodate growth of a GaAs monocrystalline semiconductor layer where x ranges from 0 to 1.

53. The process of claim 52, wherein the step of growing a second monocrystalline accommodating buffer layer comprises growing a layer of BaZrO₃ to accommodate growth of an InGaAs monocrystalline semiconductor layer.
